(19) United States
(12) Patent Application Publication
(10) Pub. No.: US 2001/0003685 A1
(43) Pub. Date: Jun. 14, 2001

(54) Electrical connector assembly with heat dissipating terminals

(76) Inventor: Yasunobu Aritani, Kanagawa (JP)

Correspondence Address: A. A. Tirva, MOLEX INCORPORATED, 2222 Wellington Court, Lisle, IL, 60532, US

(21) Appl. No.: 09/725,740

(22) Filed: Nov. 29, 2000

(30) Foreign Application Priority Data
Dec. 1, 1999 (JP) 342197/1999

(51) Int. Cl. H05K 1/00; H01R 12/00; H01R 13/00; H01R 13/648

(52) U.S. Cl. 439/485; 439/487; 439/701; 439/608; 439/79

(57) ABSTRACT

An electrical power supply connector assembly having a plurality of terminal modules mounted side by side in the connector housing. Each terminal module includes a lead frame having a main plate and a plurality of contacts and terminal legs integrally connected to the main plate and coplanar therewith. The main plate of the lead frame is embedded in an insulation resin mold, and has a heat dissipating plate projecting from the insulation resin mold.

### FIELD OF THE INVENTION

The present invention relates to an electrical connector assembly having terminal modules mounted side by side in a housing, and more particularly to such an electrical connector assembly appropriate for use in connecting a given power supply to associated electrical circuits.

### DESCRIPTION OF THE PRIOR ART

Referring to FIG. 1, a conventional electrical connector assembly (300) used to make electrical connections between printed circuit boards. The assembly has terminal modules (304) mounted side by side in a housing (305). Each terminal module (304) has a lead frame with main plates, each of which has contacts (301) and terminal legs (302) both integrally connected to a main plate and are coplanar therewith. The main plates of the lead frame are overmolded with a dielectric material. A similar electrical connector assembly is disclosed in U.S. Pat. No. 5,066,236.

Such a connector assembly may be used for transmitting electrical signals, but cannot be used for conveying electric power because of excessive heat generation; its lead frames cannot allow relatively heavy current flow because of little or no capability of dissipating the heat generated by electric current allowing the temperature of the connector assembly to rise beyond the permissible limit.

### SUMMARY OF THE INVENTION

One object of the present invention is to provide an electric power connector assembly appropriate for supplying associated electrical circuits with electrical power.

To attain this object according to the present invention each lead frame has a portion extending from its plate and from the overmolded section allowing dissipation of heat generated by the flow of electrical current through the lead assembly.

Specifically, an electrical power supply connector assembly having a plurality of terminal modules mounted side by side in a housing, is improved according to the present invention in that each terminal module includes a lead frame having a main plate, a plurality of contacts and terminal legs both integrally connected to the main plate and coplanar therewith. The main plate of each lead frame is overmolded with a dielectrical material. The main plate of each lead frame has a portion extending from the plate and from the overmolded portion.

Such an arrangement allows the heat generated by the electric current to be dissipated by the extending portion reducing the temperature rise of the connector assembly.

The overmolded portion of the lead frame may have window openings to allow the main plate to be partly exposed. This also improves dissipation of the heat generated in the lead frame.

### BRIEF DESCRIPTION OF THE DRAWINGS

Other objects and advantages of the present invention may be understood from the following description of electrical connector assemblies according to preferred embodiments of the present invention, which are shown in accompanying drawings:

FIG. 1 is a perspective view of a conventional electrical connector assembly;

FIG. 2 is a perspective view of an electrical power supply connector assembly according to a first embodiment of the present invention;

FIG. 3 is a plane view of one of the power terminal modules used in the electrical power assembly of FIG. 1;

FIG. 4 is a plane view of the lead frame of the power terminal module;

FIG. 5 is a plane view of another power terminal module having window openings formed in its insulation mold; and

FIG. 6 is a perspective view of an electrical power supply connector according to a second embodiment of the present invention.

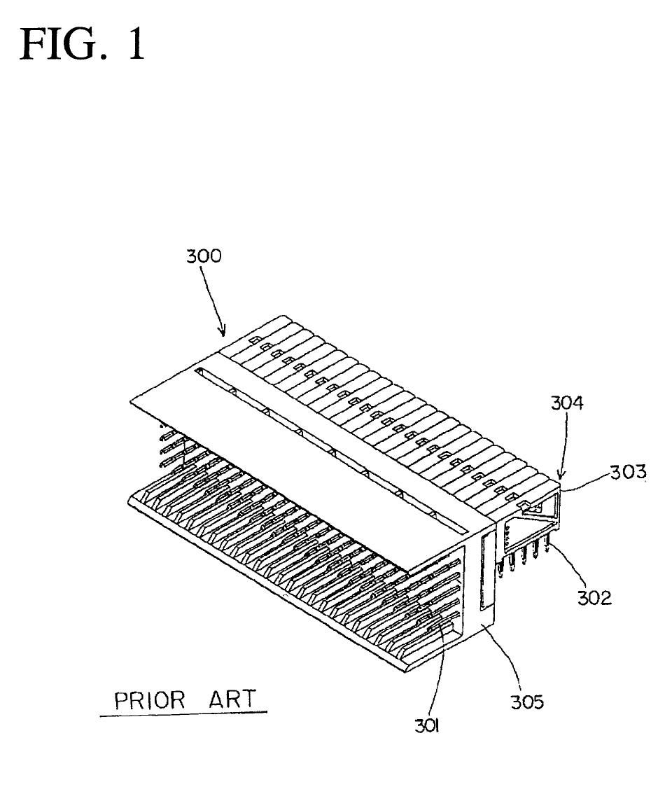

### DESCRIPTION OF THE PREFERRED EMBODIMENTS

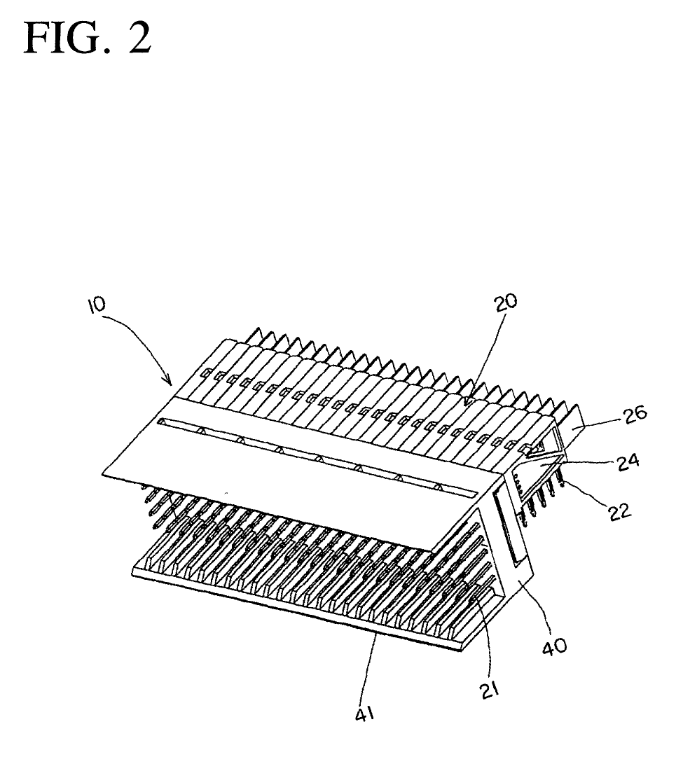

Referring to FIG. 2, an electrical power supply connector assembly (10) has a plurality of power terminal modules (20) mounted side by side in a housing (40). The connector assembly (10) has contacts (21) arranged in a lattice pattern on its front side adapted to mate with one or more mating connectors (not shown). Likewise, the connector assembly (10) has terminal legs (22) arranged in lattice pattern on its bottom side for mounting the connector assembly (10) onto a printed circuit board by inserting the terminal legs in electrically conductive through holes in the printed circuit board thereby making required electrical connections to selected conductors on the printed circuit board.

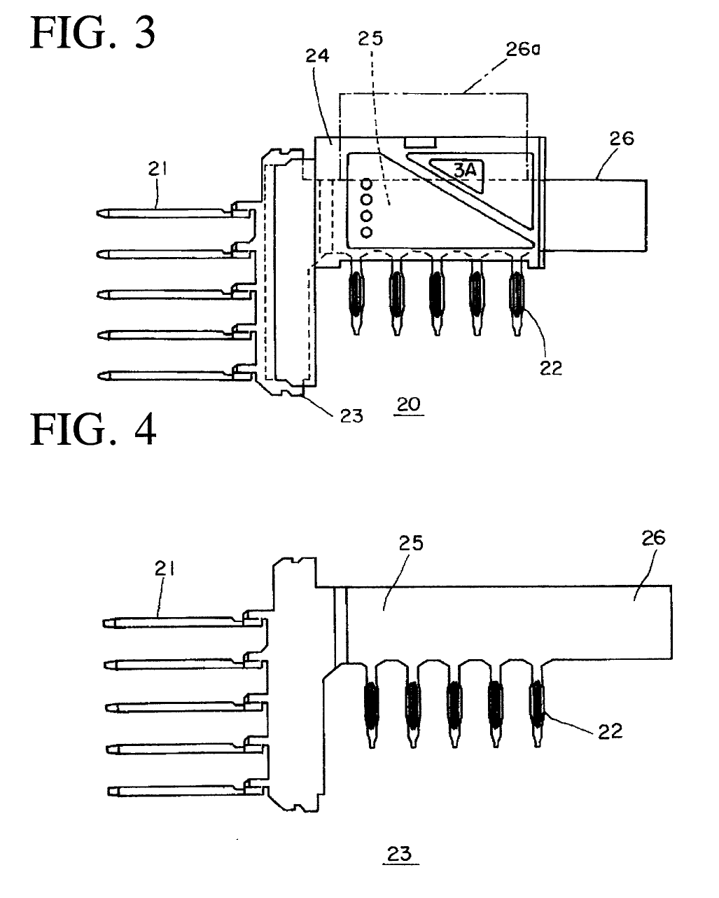

Each power terminal module (20) is composed of a lead frame (23) partially overmolded by a dielectrical material, as shown in FIG. 3.

The lead frame (23) may be made by stamping from a thin metal sheet. The lead frame has a main plate (25) and contacts (21) and terminal legs (22) both integrally connected to the main plate (25) and coplanar therewith. Specifically, the pin-like contacts (21) are arranged vertically and are integrally connected to the front edge of the vertical arm of the “L”-shaped main plate (25), and the terminal legs (22) are arranged horizontally and are integrally connected to the bottom edge of the horizontal arm of the “L”-shaped main plate (25). The main plate (25) has a rectangular portion (26) extending from the rear edge of the main plate (25). The contacts (21), terminal legs (22), main plate (25) and portion (26) are coplanar i.e. lie in one and same plane.

The lead frame (23) is partially overmolded with a dielectric material (24) substantially covering the main plate (25) thereby insulating adjacent lead frames (23) from each other when the power terminal modules (20) are mounted side by side. The portion (26) extends from the overmolded portion (24).

The contacts (21) and terminal legs (22) are integrally connected to the main plate (25) of relatively large size allowing a larger amount of electric current to flow while effectively suppressing the generation of heat. Additionally the portion (26) increases the dissipation of the heat generated in the main plate (25) preventing the temperature of each power terminal module (20) to rise beyond a permissible limit.

Extension of the portion (26) from the rear edge of the main plate (25) does not increase the height of the connecter profile. Alternatively, a portion (26a) may extend upright from the main plate (25) and from the overmolded portion (24), as shown by broken lines in FIG. 3. The upward extension of portion (26a) prevents the increase in length of the connector assembly.

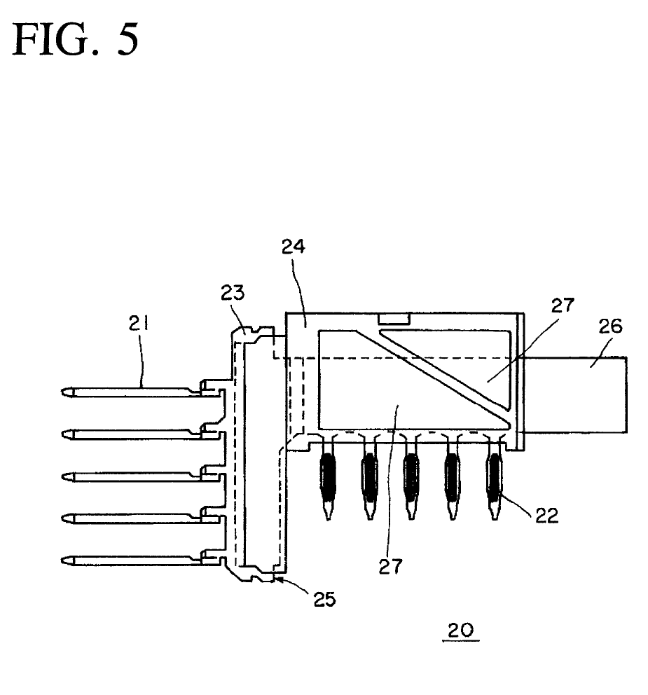

Referring to FIG. 5, window openings (27) may be made in one side or the opposite sides of the overmolded portion (24) to allow the main plate (25) to be partially exposed. This also improves the heat dissipating capability of the power terminal module (20).

In the disclosed embodiment, terminal legs (22) are press-fit type pins adapted for insertion into selected electrically conductive holes in a given printed circuit board. Alternatively, the terminal legs may be formed for soldering to such through holes. The contacts (21) may have a female type contact shape, as in a socket or receptacle.

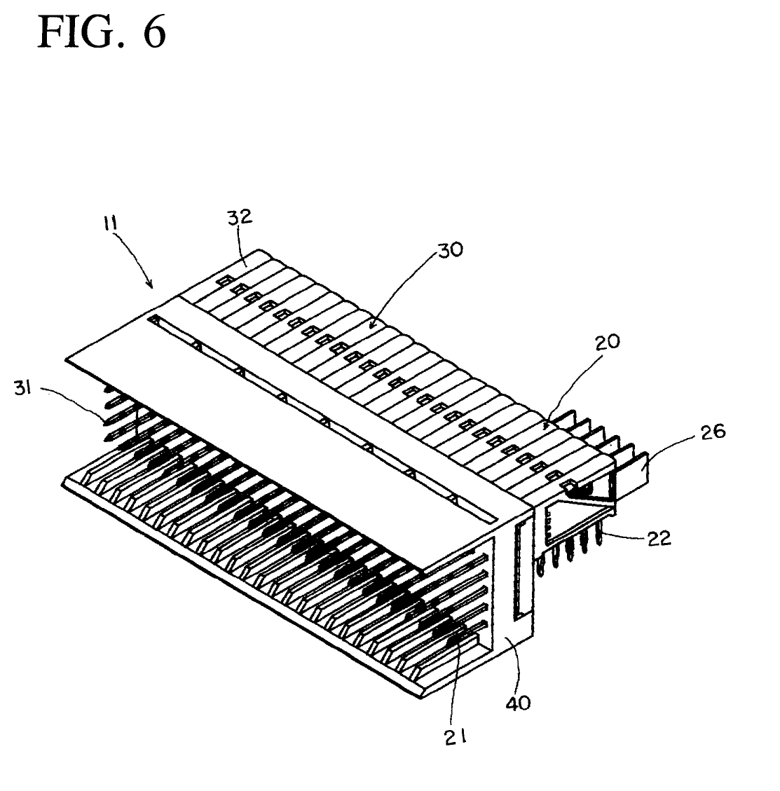

Referring to FIG. 6, an electrical connector assembly (11) according to another embodiment of the present invention includes the above described power terminal modules (20) and conventional signal terminal modules (30) arranged and mounted side by side in a housing (40). In this particular embodiment six power terminal modules (20) and nineteen signal terminal modules (30) are used, however, as many power and signal terminals may be used as required to meet occasional demands.

The signal terminal module (30) does not have an extending portion for heat dissipation. Additionally, the signal terminal module (30) is different from the power terminal module (20) in that each of two or more contacts and terminal legs are integrally connected to its own main plate. All individual lead frames are partially overmolded with a dielectric material (32) to make up a signal terminal module (30).

In use, the power terminal modules (20) of the electrical connector assembly (11) are connected to selected power lines conveying electric power whereas the signal terminal modules (30) are connected to selected signal lines conveying electrical signals. As described earlier, the power terminal modules (30) provide for effective dissipation of heat, thereby keeping the temperature of the whole connector assembly below the permissible limit.

I claim:

1. An electrical connector assembly comprising,
a housing,
a plurality of terminal modules mounted side by side in the housing,
at least one of the terminal modules adapted to convey electrical power,
the electrical power terminal module including a lead frame having a main plate, first and second plurality of terminals extending from the main plate and being substantially coplanar with the main plate,
a dielectric material encasing substantially all of the main plate, and
wherein the improvement comprises a plate portion coplanar with and extending from the main plate and from the dielectric casing for dissipation of heat generated by electric current flowing through the lead frame.

2. An electrical connector assembly according to claim 1, wherein the dielectric casing has at least one opening allowing the main plate to be partially exposed.

3. An electrical connector assembly according to claim 1, wherein the main plate has front, rear and bottom edges and wherein the first plurality of terminals extends from the front edge of the main plate and the heat dissipating plate portion extends from the rear edge of the main plate.

4. An electrical connector in accordance with claim 3, wherein the second plurality of terminals extends from the bottom edge of the main plate.

5. An electrical power supply module comprising,
a lead frame assembly having a main plate,
first and second plurality of terminals extending from the main plate and substantially coplanar with the main plate,
a dielectric material encasing substantially all of the main plate, and
wherein the improvement comprises a plate portion coplanar with and extending form the main plate and the dielectric casing for dissipation of heat generated by electric current flowing though the lead frame.
